(19) United States
(12) Patent Application Publication
(10) Pub. No.: US 2025/0221108 A1
(43) Pub. Date: Jul. 3, 2025

(54) DISPLAY DEVICE AND METHOD OF MANUFACTURING THE SAME

(71) Applicant: Samsung Display Co., LTD., Yongin-si (KR)

(72) Inventors: Hyun Eok SHIN, Yongin-si (KR); Dong Min LEE, Yongin-si (KR); Ju Hyun LEE, Yongin-si (KR); Yung Bin CHUNG, Yongin-si (KR)

(21) Appl. No.: 18/916,433

(22) Filed: Oct. 15, 2024

(30) Foreign Application Priority Data
Jan. 3, 2024 (KR) 10-2024-0001100

(51) Int. Cl. H01L 33/42; H01L 25/16; H01L 33/32; H01L 33/38

(52) U.S. Cl. CPC H10H 20/833; H01L 25/167; H10H 20/831; H10H 20/032; H10H 20/825

(57) ABSTRACT

A display device includes: a first electrode; a semiconductor stacked member including a first semiconductor layer, a second semiconductor layer, and an active layer between the first semiconductor layer and the second semiconductor layer, and located on the first electrode; and a second electrode on the semiconductor stacked member, the second electrode including: a first electrode layer on the semiconductor stacked member; a second electrode layer on the first electrode layer, the second electrode layer having a lower sheet resistance than the first electrode layer; and a third electrode layer on the second electrode layer, the third electrode layer including a transparent conductive material.

### CROSS-REFERENCE TO RELATED APPLICATION

The present application claims priority to and the benefit of Korean Patent Application No. 10-2024-0001100, filed Jan. 3, 2024, in the Korean Intellectual Property Office, the entire disclosure of which is incorporated by reference herein.

### BACKGROUND

### 1. Field

The present disclosure relates to a display device and a method of manufacturing the same.

### 2. Description of the Related Art

As information technology develops, the importance of a display device as a connection medium between a user and information is being emphasized. Accordingly, research and development on display devices are continuously being conducted.

The display device may include a light emitting element having a micro or nano scale, and the light emitting element may include a semiconductor stacked member including a P-type semiconductor and an N-type semiconductor. The light emitting element may be electrically connected to an anode electrode and a cathode electrode.

As the cathode electrode, a structure that can ensure light transmittance may be required. In this case, when the cathode electrode is formed as a single layer structure of metal to ensure light transmittance, the cathode electrode may have a high sheet resistance. This may cause defects in the display device (or the cathode electrode).

### SUMMARY

Aspects and features of embodiments of the present disclosure are to provide a display device in which defects in a cathode electrode can be reduced and a method of manufacturing the same.

One or more aspects and features of embodiments of the present disclosure are to provide a display device that can appropriately implement ohmic contact characteristics while ensuring appropriate light transmittance of a cathode electrode, and a method of manufacturing the same.

A display device according to one or more embodiments of the present disclosure may include a first electrode; a semiconductor stacked member including a first semiconductor layer, a second semiconductor layer, and an active layer between the first semiconductor layer and the second semiconductor layer, and on the first electrode; and a second electrode on the semiconductor stacked member. The second electrode may include a first electrode layer on the semiconductor stacked member; a second electrode layer on the first electrode layer, the second electrode layer having a lower sheet resistance than the first electrode layer; and a third electrode layer on the second electrode layer, the third electrode layer including a transparent conductive material.

According to one or more embodiments, the first electrode layer may include titanium (Ti) or tantalum (Ta).

According to one or more embodiments, the first electrode layer may have a thickness of 30 Å to 50 Å.

According to one or more embodiments, the second electrode layer may include silver (Ag).

According to one or more embodiments, the second electrode layer may further include zinc (Zn) or copper (Cu).

According to one or more embodiments, the second electrode layer may have a thickness of 42 Å to 58 Å.

According to one or more embodiments, the sheet resistance of the second electrode layer may be 20 Ω/sq to 30 Ω/sq.

According to one or more embodiments, the second electrode layer may be in contact with the first electrode layer.

According to one or more embodiments, the third electrode layer may include indium zinc oxide (IZO).

According to one or more embodiments, the third electrode layer may have a thickness of 1000 Å to 3000 Å.

According to one or more embodiments, the first electrode layer, the second electrode layer, and the third electrode layer may have ends that coincide with each other.

According to one or more embodiments, the display device may further include an intermediate insulating layer on a same layer as the first electrode layer. The intermediate insulating layer may be formed integrally with the first electrode layer, and the intermediate insulating layer may include titanium oxide (TiOx) or tantalum oxide (TaOx).

According to one or more embodiments, the second electrode layer may be in contact with the first electrode layer and the third electrode layer, and an upper surface of the intermediate insulating layer may be exposed by the second electrode layer and the third electrode layer.

A method of manufacturing a display device according to one or more embodiments of the present disclosure may include patterning a first electrode on a base layer; forming a semiconductor stacked member on the first electrode; and patterning a second electrode on the semiconductor stacked member. The patterning the second electrode may include forming a first electrode layer on the semiconductor stacked member, the first electrode layer including titanium (Ti) or tantalum (Ta); forming a second electrode layer on the first electrode layer, the second electrode layer having a lower sheet resistance than the first electrode layer; and forming a third electrode layer on the second electrode layer, the third electrode layer including a transparent conductive material.

According to one or more embodiments, the forming the first electrode layer on the semiconductor stacked member may include depositing a first base electrode layer to have a thickness of 30 Å to 50 Å on the semiconductor stacked member.

According to one or more embodiments, the forming the second electrode layer on the first electrode layer may include depositing a second base electrode layer on the first base electrode layer. The second base electrode layer may include silver (Ag) and has a thickness of 42 Å to 58 Å.

According to one or more embodiments, the forming the third electrode layer on the second electrode layer may include depositing a third base electrode layer on the second base electrode layer. The third base electrode layer may include indium zinc oxide (IZO) and has a thickness of 1000 Å to 3000 Å.

According to one or more embodiments, the patterning the second electrode may include etching the first base electrode layer, the second base electrode layer, and the third base electrode layer. The first base electrode layer, the second base electrode layer, and the third base electrode layer may be etched to have ends that coincide with each other.

According to one or more embodiments, the first base electrode layer may be etched by an etchant including hydrogen fluoride (HF), and the second base electrode layer and the third base electrode layer may be wet etched.

According to one or more embodiments, the patterning the second electrode may include etching the second base electrode layer and the third base electrode layer. The second base electrode layer and the third base electrode layer may be etched to expose at least a portion of the first base electrode layer that does not overlap the semiconductor stacked member in a plan view.

### BRIEF DESCRIPTION OF THE DRAWINGS

The accompanying drawings, which are included to provide a further understanding of the present disclosure, and are incorporated in and constitute a part of the present disclosure, illustrate embodiments of the present disclosure, and, together with the description, serve to explain principles and scope of the present disclosure.

FIG. 1 is a plan view schematically illustrating a display device according to one or more embodiments.

FIG. 2 is a schematic cross-sectional view of a display device according to one or more embodiments.

FIG. 3 is a schematic cross-sectional view of a display device according to one or more embodiments.

FIG. 4 is a flowchart illustrating a method of manufacturing a display device according to one or more embodiments.

FIG. 5 is a flowchart illustrating S200 of FIG. 4 in a method of manufacturing a display device according to one or more embodiments.

FIGS. 6-8 are cross-sectional views schematically illustrating each process in the method of manufacturing the display device according to one or more embodiments.

FIGS. 9 and 10 are cross-sectional views schematically illustrating each process in a method of manufacturing a display device according to one or more embodiments.

FIG. 11 is a flowchart illustrating a step S200 of FIG. 4 in a method of manufacturing a display device according to one or more embodiments.

FIG. 12 is a cross-sectional view schematically illustrating each process in the method of manufacturing the display device according to one or more embodiments.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and/or substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the spirit or scope of the present disclosure. Similarly, the second element could also be termed the first element. In the present disclosure, the singular expressions are intended to include the plural expressions as well, unless the context clearly indicates otherwise.

It will be further understood that the terms “comprise”, “include”, “have”, etc. used in the present disclosure, specify the presence of stated features, integers, steps, operations, elements, components, and/or combinations of them but do not preclude the presence or addition of one or more other features, integers, steps, operations, elements, components, and/or combinations thereof. In addition, when a first part such as a layer, film, region, plat, etc. is on a second part, the first part may be not only “directly on” the second part but a third part may intervene between them. Furthermore, in the present disclosure, when a first part such as a layer, film, region, plat, etc. is formed on a second part, a direction in which the first part is formed is not limited to an upper direction of the second part, but may include a side or a lower direction of the second part. To the contrary, when a first part such as a layer, film, region, plat, etc. is “under” a second part, the first part may be not only “directly under” the second part but a third part may intervene between them.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The present disclosure relates to a display device and a method of manufacturing the same. Hereinafter, the display device and the method of manufacturing the same according to embodiments of the present disclosure will be described with reference to the accompanying drawings.

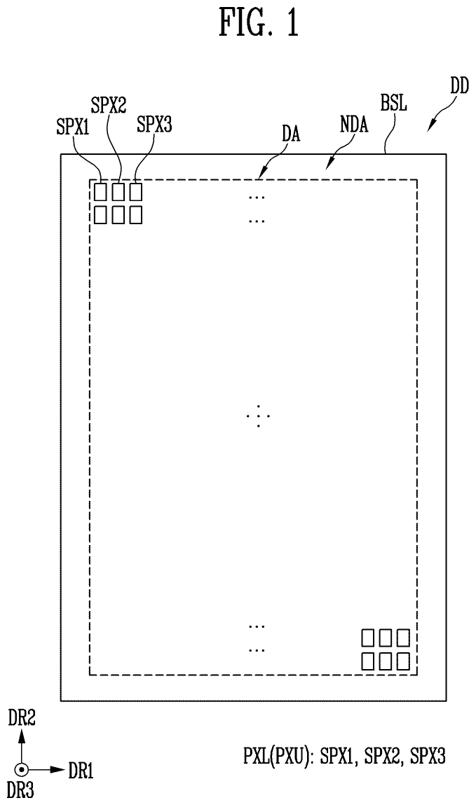

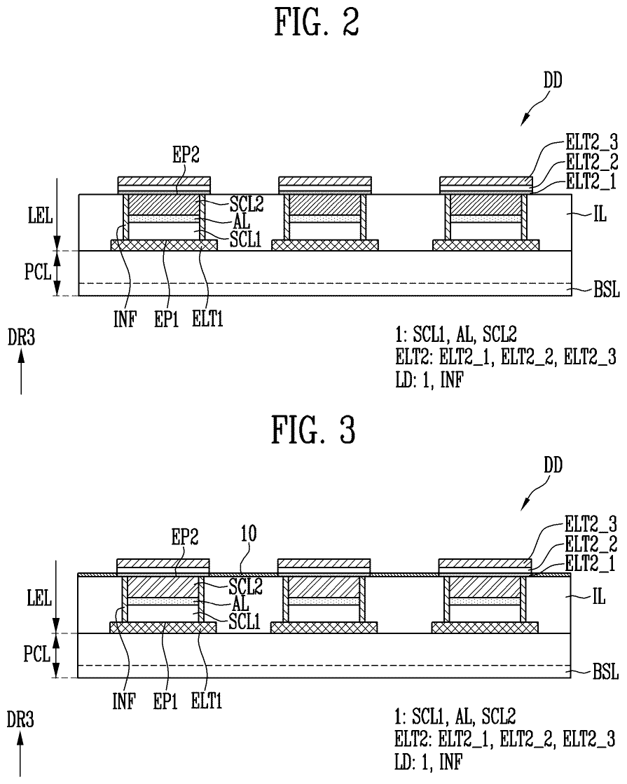

First, a display device DD according to one or more embodiments will be described with reference to FIGS. 1 and 2.

FIG. 1 is a plan view schematically illustrating a display device according to one or more embodiments. FIG. 2 is a schematic cross-sectional view of a display device according to one or more embodiments.

Referring to FIG. 1, the display device DD may be configured to emit light. The display device DD may include a light emitting element LD. According to one or more embodiments, the display device DD may be a device that displays a moving image and/or a still image. The display device DD may be used as display screens for various products such as television, a laptop, a monitor, a billboard, and/or an Internet of Things (IOT) as well as portable electronic devices such as a mobile phone, a smart phone, a tablet personal computer, a smart watch, a watch phone, a mobile communication terminal, an electronic notebook, an e-book, a portable multimedia player (PMP), a navigation, and/or an UMPC (Ultra Mobile PC). However, the application field of the display device DD is not limited to specific examples.

The display device DD may be formed in the form of a rectangular flat plate having a short side in a first direction DR1 and a long side in a second direction DR2 that intersects the first direction DR1. A corner portion where the short side in the first direction DR1 and the long side in the second direction DR2 meet may be rounded to have a curvature or may be formed at a right angle. The planar shape of the display device DD is not limited to a rectangular shape, but may be formed in another polygonal shape or a round shape such as a circle or an oval. The display device DD may be formed flat, but the present disclosure is not limited thereto. For example, the display device DD may include a curved portion formed at left and right ends and having a constant curvature or a changing curvature. In addition, the display device DD may be flexible so that it can be curved, bent, folded, and/or rolled.

In the present disclosure, the first direction DR1 may be a row direction of pixels PXL and may be a “horizontal” direction. The second direction DR2 may be a column direction of the pixels PXL. A third direction DR3 may be a display direction of the display device DD or a normal direction of a plane where a base layer BSL is disposed.

The display device DD may include a display area DA and a non-display area NDA around an edge or a periphery of the display area DA. The non-display area NDA may refer to an area except the display area DA. The non-display area NDA may surround at least a portion of the display area DA.

The display area DA may refer to an area where the pixels PXL are disposed. The non-display area NDA may refer to an area where the pixels PXL are not disposed. A driving circuit unit, wirings, and pads connected to the pixels PXL of the display area DA may be disposed in the non-display area NDA.

According to one or more embodiments, a pixel PXL (or sub-pixels SPX) may include a first sub-pixel SPX1, a second sub-pixel SPX2, and a third sub-pixel SPX3. At least one first sub-pixel SPX1, second sub-pixel SPX2, and third sub-pixel SPX3 may form one pixel unit PXU capable of emitting light of various colors. FIG. 1 shows an example where each pixel PXL includes three sub-pixels SPX1, SPX2, and SPX3, that is, the first sub-pixel SPX1, the second sub-pixel SPX2, and the third sub-pixel SPX3, but the present disclosure is not limited thereto.

According to one or more embodiments, the pixel PXL (or sub-pixels SPX1, SPX2, SPX3) may be arranged in a structure such as a stripe, PENTILE®, or the like. However, the present disclosure is not necessarily limited thereto. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

The first sub-pixel SPX1 may emit first light, the second sub-pixel SPX2 may emit second light, and the third sub-pixel SPX3 may emit third light. Here, the first light may be light in a red wavelength band, the second light may be light in a green wavelength band, and the third light may be light in a blue wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm, but the present disclosure is not limited thereto.

Each of the first sub-pixel SPX1, the second sub-pixel SPX2, and the third sub-pixel SPX3 may include an inorganic light emitting element including an inorganic material that emits light. For example, the light emitting element LD may be an inorganic light emitting element including an inorganic semiconductor and may be a micro light emitting diode (LED).

Referring to FIG. 2, the display device DD may include a pixel circuit layer PCL and a light emitting element layer LEL.

The pixel circuit layer PCL may be a layer including a pixel circuit for driving light emitting elements LD. The pixel circuit layer PCL may include a base layer BSL, conductive layers for forming pixel circuits, and insulating layers disposed between the conductive layers.

According to one or more embodiments, the pixel circuit may include circuit elements (for example, a driving transistor and the like) and may be electrically connected to the light emitting elements LD to provide an electrical signal so that the light emitting elements LD emit light.

The light emitting element layer LEL may be disposed on the pixel circuit layer PCL. The light emitting element layer LEL may include the light emitting elements LD, a first electrode ELT1, a second electrode ELT2, and an intermediate layer IL.

The light emitting element LD may be disposed on the pixel circuit layer PCL (or the base layer BSL). According to one or more embodiments, the light emitting element LD may include a semiconductor stacked member 1 and an insulating film INF.

The light emitting element LD may have various sizes. According to one or more embodiments, the light emitting element LD may have a size ranging from a micro scale to a nano scale. However, the present disclosure is not limited thereto.

The semiconductor stacked member 1 may include a first semiconductor layer SCL1, a second semiconductor layer SCL2, and an active layer AL disposed between the first semiconductor layer SCL1 and the second semiconductor layer SCL2.

The semiconductor stacked member 1 may have a first end EP1 and a second end EP2. According to one or more embodiments, the first semiconductor layer SCL1 may be adjacent to the first end EP1 of the semiconductor stacked member 1, and the second semiconductor layer SCL2 may be adjacent to the second end EP2 of the semiconductor stacked member 1.

The first semiconductor layer SCL1 may be disposed on one side of the active layer AL and may include a P-type semiconductor according to one or more embodiments. For example, the first semiconductor layer SCL1 may include one or more of P-type doped AlGaInN, GaN, AlGaN, InGaN, AlN, and/or InN. The first semiconductor layer SCL1 may be doped with a P-type dopant, and the P-type dopant may be Mg, Zn, Ca, Ba, and/or the like. For example, the first semiconductor layer SCL1 may be P-GaN doped with a P-type dopant. However, the present disclosure is not limited thereto, and the first semiconductor layer SCL1 may include various types of known P-type semiconductor materials.

The active layer AL may be disposed between the first semiconductor layer SCL1 and the second semiconductor layer SCL2. The active layer AL may include a single-quantum well or multi-quantum well structure. The position of the active layer AL is not limited to a specific example and may vary depending on the type of light emitting element LD.

The active layer AL may include a well layer and a barrier layer to form a quantum well structure. According to one or more embodiments, the active layer AL may include at least one of GaInP, AlGaInP, GaAs, AlGaAs, InP, and/or InAs. However, the present disclosure is not limited thereto, and the active layer AL may include various types of known semiconductor materials.

The second semiconductor layer SCL2 may be disposed on the other side of the active layer AL, and may include an N-type semiconductor according to one or more embodiments. For example, the second semiconductor layer SCL2 may include one or more of N-type doped AlGaInN, GaN, AlGaN, InGaN, AlN, and/or InN. The second semiconductor layer SCL2 may be doped with an N-type dopant, and the N-type dopant may be Si, Ge, Sn, and/or the like. For example, the second semiconductor layer SCL2 may be N-GaN doped with an N-type dopant. However, the present disclosure is not limited thereto, and the second semiconductor layer SCL2 may include various types of known N-type semiconductor materials.

The first end EP1 of the semiconductor stacked member 1 may be electrically connected to the first electrode ELT1 disposed on the pixel circuit layer PCL. The second end EP2 of the semiconductor stacked member 1 may be electrically connected to the second electrode ELT2 disposed on the semiconductor stacked member 1. When a voltage higher than a threshold voltage is applied between the first end EP1 and the second end EP2 of the semiconductor stacked member 1, electron-hole pairs may recombine with each other in the active layer AL, and the light emitting element LD may emit light.

According to one or more embodiments, the first electrode ELT1 may be an anode electrode, and the second electrode ELT2 may be a cathode electrode.

According to one or more embodiments, the first electrode ELT1 may have a single-layer structure or a multi-layer stacked structure including two or more layers.

According to one or more embodiments, the first electrode ELT1 may include a conductive material. For example, the conductive material may include one or more selected from the group consisting of gold (Au), silver (Ag), aluminum (Al), molybdenum (Mo), chromium (Cr), titanium (Ti), nickel (Ni), neodymium (Nd), copper (Cu), and platinum (Pt). Alternatively, according to one or more embodiments, the conductive material may include one or more selected from the group consisting of silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO₂), carbon nano tube, and graphene. However, the present disclosure is not necessarily limited thereto.

According to one or more embodiments, the second electrode ELT2 may have a multi-layer structure including two or more layers. For example, the second electrode ELT2 may include a first electrode layer ELT2_1, a second electrode layer ELT2_2 disposed on the first electrode layer ELT2_1, and a third electrode layer ELT2_3 disposed on the second electrode layer ELT2_2.

The second electrode ELT2 of the light emitting element LD according to the present disclosure may have a stacked structure including two or more layers, and defects in the light emitting element LD (or the second electrode ELT2) can be reduced. Hereinafter, the stacked structure of the second electrode ELT2 will be described.

The first electrode layer ELT2_1 may be a lower layer of the second electrode ELT2. The first electrode layer ELT2_1 may be disposed on the second semiconductor layer SCL2 of the light emitting element LD. At least a portion of the first electrode layer ELT2_1 may be in contact with the second semiconductor layer SCL2 of the light emitting element LD. At least a portion of the first electrode layer ELT2_1 may entirely overlap the second semiconductor layer SCL2 in a plan view.

According to one or more embodiments, the first electrode layer ELT2_1 may have a structure that protrudes further outward (for example, in a direction of the plane in which the base layer BSL is disposed) than the second semiconductor layer SCL2. According to one or more embodiments, at least a portion of the first electrode layer ELT2_1 may not overlap with at least a portion of the second semiconductor layer SCL2 in a plan view.

According to one or more embodiments, the first electrode layer ELT2_1 may include one or more of titanium (Ti) and/or tantalum (Ta). Experimentally, titanium (Ti) and/or tantalum (Ta) can appropriately implement ohmic contact characteristics between a semiconductor and a metal. The first electrode layer ELT2_1 may include titanium (Ti) and/or tantalum (Ta). The first electrode layer ELT2_1 may be an electrode for ohmic contact between the semiconductor stacked member 1 and an electrode (for example, the second electrode layer ELT2_2 and the third electrode layer ELT2_3) disposed on the first electrode layer ELT2_1, and may function as an ohmic electrode.

According to one or more embodiments, the first electrode layer ELT2_1 may have a thickness of 30 Å to 50 Å. Experimentally, in the case of a metal layer including titanium (Ti), in order for light transmittance of the metal layer to exceed 80%, the metal layer needs to be formed to have a thickness of 70 Å or less. The first electrode layer ELT2_1 according to the present disclosure may have a thickness of 30 Å to 50 Å. Accordingly, reduction in light transmittance in the light emitting element LD can be reduced or minimized, and light transmittance can be appropriately secured.

The second electrode layer ELT2_2 may be an intermediate layer of the second electrode ELT2. The second electrode layer ELT2_2 may be disposed on the first electrode layer ELT2_1. The second electrode layer ELT2_2 may be in contact with the first electrode layer ELT2_1. The second electrode layer ELT2_2 may entirely overlap the first electrode layer ELT2_1 in a plan view. At least a portion of the second electrode layer ELT2_2 may entirely overlap the second semiconductor layer SCL2 in a plan view.

According to one or more embodiments, the second electrode layer ELT2_2 may have a structure that protrudes further outward (for example, in a direction of the plane where the base layer BSL is disposed) than the second semiconductor layer SCL2. According to one or more embodiments, at least a portion of the second electrode layer ELT2_2 may not overlap with at least a portion of the second semiconductor layer SCL2 in a plan view.

The second electrode layer ELT2_2 may have ends that correspond to ends of the first electrode layer ELT2_1. The second electrode layer ELT2_2 may have ends that coincide with ends of the first electrode layer ELT2_1. For example, the ends of the second electrode layer ELT2_2 and the ends of the first electrode layer ELT2_1 may overlap each other in a plan view.

According to one or more embodiments, the second electrode layer ELT2_2 may include silver (Ag). According to one or more embodiments, the second electrode layer ELT2_2 may include an alloy including silver (Ag). For example, the second electrode layer ELT2_2 may include one or more of zinc (Zn) and/or copper (Cu) and silver (Ag). According to one or more embodiments, the second electrode layer ELT2_2 may include a ternary silver (Ag) alloy formed of three elements.

According to one or more embodiments, the second electrode layer ELT2_2 may have a thickness of 42 Å to 58 Å. Experimentally, in the case of a metal layer including silver (Ag), when the metal layer has a thickness of 150 Å or more, light transmittance of the metal layer may be reduced to 50% or less. Accordingly, in the case of a metal layer including silver (Ag), in order for light transmittance of the metal layer to exceed 80%, the metal layer needs to be formed to have a thickness of 60 Å or less.

Experimentally, when a metal layer including silver (Ag) has a thickness of 42 Å to 58 Å, light transmittance of the metal layer may be 90% or more. The second electrode layer ELT2_2 according to the present disclosure may have a thickness of 42 Å to 58 Å. Accordingly, reduction in light transmittance in the light emitting element LD can be reduced or minimized and light transmittance can be appropriately secured.

In addition, experimentally, silver (Ag) may have lower thin film resistivity properties than other metals. For example, silver (Ag) may have a resistivity that is about 1/20 times lower than that of titanium (Ti). Accordingly, the second electrode layer ELT2_2 may include silver (Ag), may have a thickness of 42 Å to 58 Å, and may have a lower sheet resistance than the first electrode layer ELT2_1. The sheet resistance of the second electrode layer ELT2_2 may be 30 Ω/sq or less. The sheet resistance of the second electrode layer ELT2_2 formed of a ternary alloy including silver (Ag) and/or zinc (Zn) may be 20 Ω/sq or more and 30 Ω/sq or less. The sheet resistance of the second electrode layer ELT2_2 formed of a ternary alloy including silver (Ag) and/or copper (Cu) may be 20 Ω/sq or more and 30 Ω/sq or less.

A cathode electrode of a conventional light emitting element LD includes only a first electrode layer ELT2_1 including a metal such as titanium (Ti), and the cathode electrode has a single metal layer structure. In this case, the cathode electrode is formed to be thin so that light can be transmitted. However, because a single metal layer having a thin thickness (e.g., a reduced thickness) has high sheet resistance, a voltage drop at the cathode electrode may occur frequently. Compared to this, according to the present disclosure, as the second electrode layer ELT2_2 is disposed on the first electrode layer ELT2_1, a voltage drop at the cathode electrode (for example, the second electrode ELT2) of the light emitting element LD can be reduced or minimized.

The third electrode layer ELT2_3 may be an upper layer of the second electrode ELT2. The third electrode layer ELT2_3 may be disposed on the second electrode layer ELT2_2. The third electrode layer ELT2_3 may be in contact with the second electrode layer ELT2_2. The third electrode layer ELT2_3 may entirely overlap the first electrode layer ELT2_1 and the second electrode layer ELT2_2 in a plan view. At least a portion of the third electrode layer ELT2_3 may entirely overlap the second semiconductor layer SCL2 in a plan view.

According to one or more embodiments, the third electrode layer ELT2_3 may have a structure that protrudes further outward (for example, in a direction of the plane where the base layer BSL is disposed) than the second semiconductor layer SCL2. According to one or more embodiments, at least a portion of the third electrode layer ELT2_3 may not overlap with at least a portion of the second semiconductor layer SCL2 in a plan view.

The third electrode layer ELT2_3 may have ends that coincide with the ends of the second electrode layer ELT2_2. For example, the third electrode layer ELT2_3 and the second electrode layer ELT2_2 may be manufactured in a same etching process. Accordingly, the ends of each of the third electrode layer ELT2_3 and the second electrode layer ELT2_2 may overlap each other in a plan view.

According to one or more embodiments, the third electrode layer ELT2_3 may have ends corresponding to the ends of the first electrode layer ELT2_1 and the second electrode layer ELT2_2. The third electrode layer ELT2_3 may have ends that coincide with the ends of the first electrode layer ELT2_1 and the second electrode layer ELT2_2. For example, the ends of the third electrode layer ELT2_3 and the ends of the first electrode layer ELT2_1 and the second electrode layer ELT2_2 may overlap each other in a plan view.

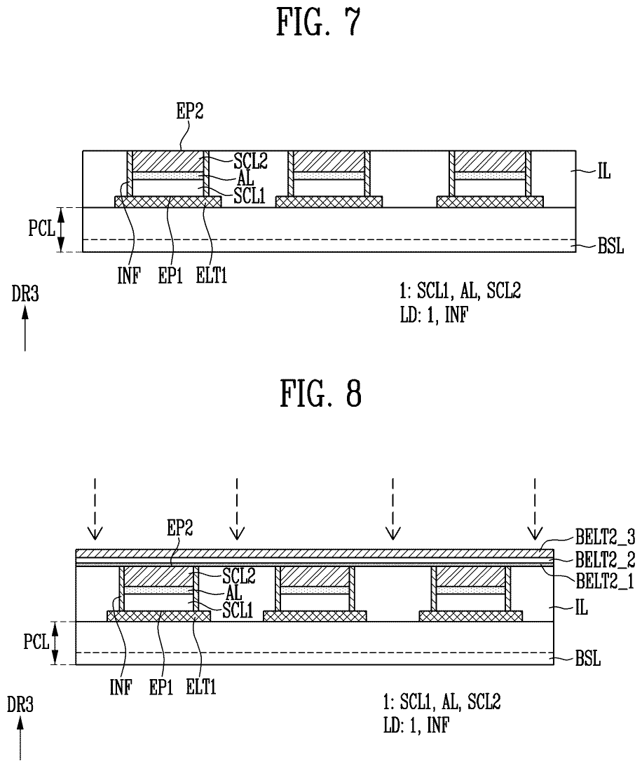

According to one or more embodiments, the third electrode layer ELT2_3 may include a transparent conductive oxide (TCO) material. According to one or more embodiments, the third electrode layer ELT2_3 may include one or more selected from the group consisting of indium tin oxide (ITO), indium zinc oxide (IZO), indium gallium zinc oxide (IGZO), and aluminum zinc oxide (AZO). According to one or more embodiments, when the third electrode layer ELT2_3 includes indium zinc oxide (IZO), the third electrode layer ELT2_3 may be easily etched in the process of forming the third electrode layer ELT2_3. This will be described later with reference to the drawings after FIG. 8.

According to one or more embodiments, as the third electrode layer ELT2_3 includes a transparent conductive material, the third electrode layer ELT2_3 may have high light transmittance regardless of the thickness of the third electrode layer ELT2_3.

According to one or more embodiments, the third electrode layer ELT2_3 may have a thickness of 1000 Å to 3000 Å. The third electrode layer ELT2_3 may have a greater thickness than the first electrode layer ELT2_1 and the second electrode layer ELT2_2. When the third electrode layer ELT2_3 is formed to have a thickness of 1000 Å to 3000 Å, the second electrode layer ELT2_2 disposed below the third electrode layer ELT2_3 can be appropriately protected, and a step difference below the third electrode layer ELT2_3 can be offset. Accordingly, the third electrode layer ELT2_3 can be stably electrically connected to the second electrode layer ELT2_2, and electrical resistance can be reduced.

According to one or more embodiments, the structure of the light emitting element LD is not limited to the examples described above and may further include additional layer(s). For example, the light emitting element LD may further include an electron blocking layer to prevent or reduce electron overflow. In addition, the light emitting element LD may further include a superlattice layer to relieve stress inside the light emitting element LD.

The insulating film INF may be around (e.g., may surround) the side (e.g., an outer peripheral or circumferential surface) of the semiconductor stacked member 1. The insulating film INF may be disposed on the semiconductor stacked member 1 including the first semiconductor layer SCL1, the active layer AL, and the second semiconductor layer SCL2. According to one or more embodiments, the insulating film INF may be in contact with at least a portion of the first electrode layer ELT2_1. According to one or more embodiments, the insulating film INF may overlap at least a portion of the second electrode ELT2 in a plan view. The insulating film INF may protect the semiconductor stacked member 1 from external influences and insulate the first semiconductor layer SCL1, the active layer AL, and the second semiconductor layer SCL2 from the outside.

The insulating film INF may include an insulating material including a metal oxide. For example, the insulating film INF may include a silicon oxide and/or a metal oxide including one or more metals selected from the group consisting of tantalum (Ta), hafnium (Hf), zirconium (Zr), lanthanum (La), titanium (Ti), and aluminum (Al). However, the present disclosure is not limited to specific examples.

The intermediate layer IL may be disposed on the pixel circuit layer PCL. The intermediate layer IL may be disposed between the light emitting elements LD. According to one or more embodiments, the intermediate layer IL may be an insulating layer. The intermediate layer IL may fill at least a portion of the space between the light emitting elements LD.

According to one or more embodiments, the intermediate layer IL may include an organic material and/or an inorganic material. For example, the organic material may include one or more selected from the group consisting of an acryl resin, an epoxy resin, a phenol resin, a polyamide resin, a polyimide resin, a polyester resin, a polyphenylenesulfide resin, and benzocyclobutene. For example, the inorganic material may include one or more selected from the group consisting of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and silicon oxynitride (SiOxNy). However, the present disclosure is not limited thereto.

According to one or more embodiments, the display device DD may further include an encapsulation film. The encapsulation film may be disposed on the light emitting element LD (for example, the second electrode ELT2). The encapsulation film may offset a step difference caused by the light emitting element LD. The encapsulation film may include a plurality of insulating films covering the light emitting element LD. According to one or more embodiments, the encapsulation film may have a structure in which inorganic films and organic films are alternately stacked.

Hereinafter, a display device DD according to one or more embodiments will be described with reference to FIG. 3. FIG. 3 is a schematic cross-sectional view of a display device according to one or more embodiments.

Compared to the embodiment of FIG. 2, the embodiment of FIG. 3 has a difference in that the display device DD further includes an intermediate insulating layer 10. Hereinafter, description of content that overlaps with the above-described content will be omitted.

The intermediate insulating layer 10 may be disposed between first electrode layers ELT2_1. The intermediate insulating layer 10 may be disposed between the light emitting elements LD. The intermediate insulating layer 10 may not overlap the semiconductor stacked member 1 in a plan view. The intermediate insulating layer 10 may be disposed on the intermediate layer IL. The intermediate insulating layer 10 may be in contact with the intermediate layer IL. An upper surface of the intermediate insulating layer 10 may be exposed by the second electrode layer ELT2_2 and the first electrode layer ELT2_1. An upper surface of the intermediate insulating layer 10 may also be exposed by the third electrode layer ELT2_3.

The intermediate insulating layer 10 may be in contact with a side surface of the first electrode layer ELT2_1. The intermediate insulating layer 10 may be connected to the first electrode layer ELT2_1. The intermediate insulating layer 10 may be formed in a same process as the first electrode layer ELT2_1. The intermediate insulating layer 10 may be formed integrally with the first electrode layer ELT2_1. For example, the intermediate insulating layer 10 may be deposited in the same process as the first electrode layer ELT2_1. The intermediate insulating layer 10 may be a layer that is deposited in the same process as the first electrode layer ELT2_1 and then not removed through a separate etching process.

The intermediate insulating layer 10 may include the same element as the first electrode layer ELT2_1. For example, according to one or more embodiments, the intermediate insulating layer 10 may include titanium oxide (TiOx) or tantalum oxide (TaOx), which are oxidized forms of titanium (Ti) or tantalum (Ta). As the intermediate insulating layer 10 includes a metal oxide, the intermediate insulating layer 10 can prevent current from flowing between the light emitting elements LD.

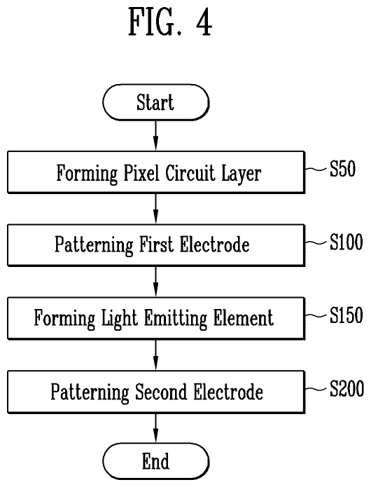

Hereinafter, a method of manufacturing a display device DD according to one or more embodiments will be described with reference to FIGS. 4 to 10.

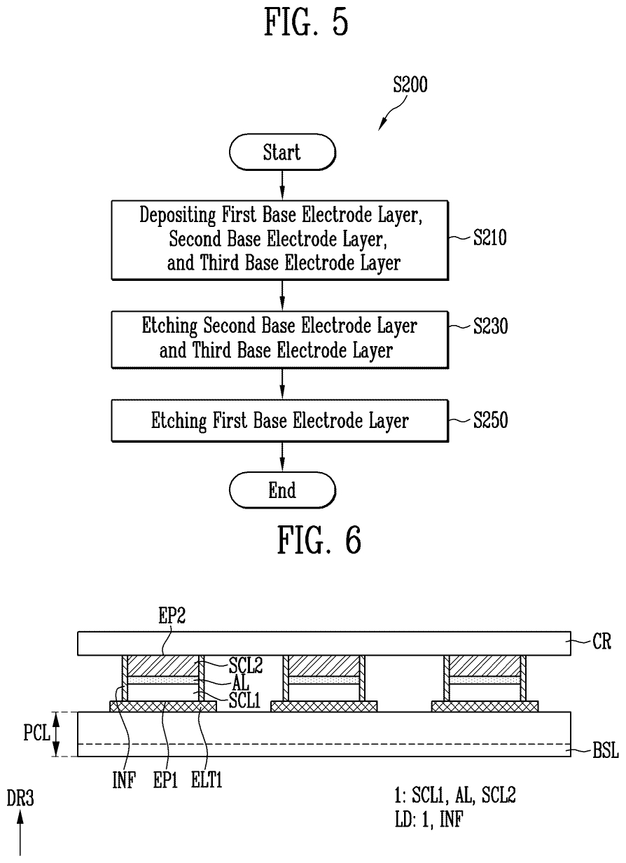

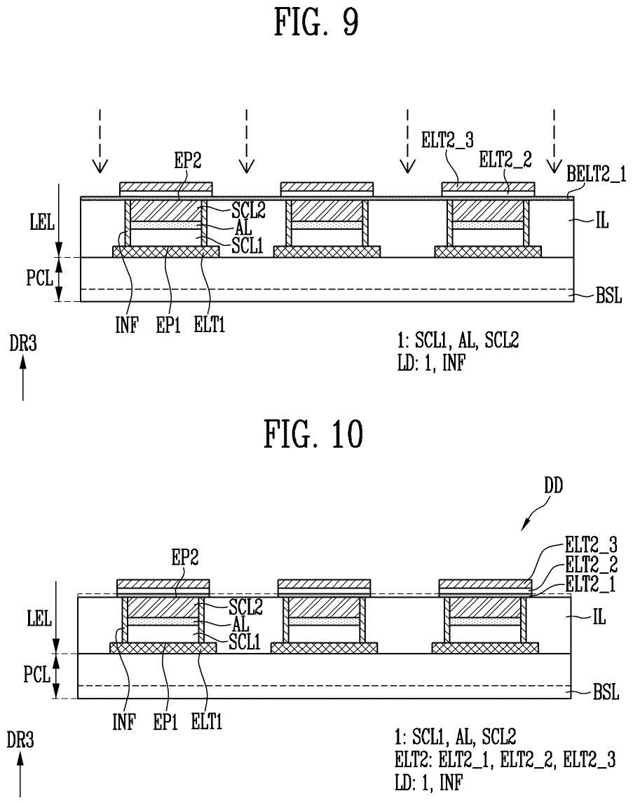

FIG. 4 is a flowchart illustrating a method of manufacturing a display device according to one or more embodiments. FIG. 4 may be a flowchart illustrating a method of manufacturing the display device DD including the embodiments of FIGS. 2 and 3. FIG. 5 is a flowchart illustrating a step S200 in FIG. 4 in a method of manufacturing a display device according to one or more embodiments. FIGS. 6-8 are cross-sectional views schematically illustrating each process in the method of manufacturing the display device according to one or more embodiments. FIGS. 6-8 may be cross-sectional views schematically illustrating each process in the method of manufacturing the display device DD including the first and second embodiments. FIGS. 9 and 10 are cross-sectional views schematically illustrating each process in a method of manufacturing a display device according to one or more embodiments.

Referring to FIGS. 4-6, the method of manufacturing the display device DD may include forming a pixel circuit layer (S50), patterning a first electrode (S100), forming a light emitting element (S150), and patterning a second electrode (S200).

In the forming the pixel circuit layer (S50), a pixel circuit layer PCL including a pixel circuit for driving light emitting elements LD may be formed (for example, patterned) on a base layer BSL. The pixel circuit layer PCL may be formed (for example, patterned) to include conductive layers and insulating layers disposed between the conductive layers.

According to one or more embodiments, components disposed on the base layer BSL may be formed (for example, patterned) through conventional patterning processes (for example, a photolithography process and the like) using masks.

In the patterning the first electrode (S100), a first electrode ELT1 may be formed (for example, patterned) on the pixel circuit layer PCL (or the base layer BSL). According to one or more embodiments, the first electrode ELT1 may be deposited on the pixel circuit layer PCL and then etched to expose at least a portion of the pixel circuit layer PCL.

In the present disclosure, unless otherwise described regarding a deposition process used to form (for example, patterning) the components of the display device DD, one or more of a sputtering process, a chemical vapor deposition (CVD) process, and an atomic layer deposition (ALD) process may be used as the deposition process for forming the components of the display device DD. In the present disclosure, unless otherwise described regarding an etching process used to form (for example, patterning) the components of the display device DD, one or more of a wet etching process and a dry etching process may be used as the etching process. However, the present disclosure is not limited to specific examples.

In the forming the light emitting element (S150), light emitting elements LD may be disposed on the pixel circuit layer PCL. The light emitting element LD may be disposed on the first electrode ELT1.

The light emitting element LD may be manufactured by patterning on a separate wafer. For example, the light emitting element LD including a semiconductor stacked member 1 and an insulating film INF may be patterned on one wafer and then transferred onto the pixel circuit layer PCL using a carrier wafer CR. However, the present disclosure is not limited thereto.

The method by which the light emitting element LD is patterned on a wafer is not particularly limited. For example, semiconductor layers for forming the semiconductor stacked member 1 may be epitaxially grown on a wafer and then etched to manufacture the semiconductor stacked member 1, and a conventional process may be performed to manufacture the insulating film INF. For example, layers for forming a first semiconductor layer SCL1, an active layer AL, and a second semiconductor layer SCL2 are epitaxially grown on a wafer and then etched to manufacture the semiconductor stacked member 1, and the insulating film INF may be patterned on the semiconductor stacked member 1.

Referring to FIG. 7, after the light emitting element LD is formed, forming an intermediate layer IL may be further performed. The intermediate layer IL may be disposed between the light emitting elements LD. According to one or more embodiments, the intermediate layer IL may include an organic material and/or an inorganic material.

Referring to FIGS. 5 and 8, after the light emitting element LD is formed, a second electrode ELT2 may be patterned on the light emitting element LD.

The patterning the second electrode (S200) may include depositing a first base electrode layer, a second base electrode layer, and a third base electrode layer (S210), etching the second base electrode layer and the third base electrode layer (S230), and etching the first base electrode layer (S250).

Referring to FIG. 8, the depositing the first base electrode layer, the second base electrode layer, and the third base electrode layer (S210) may include depositing a first base electrode layer BELT2_1 on the second semiconductor layer SCL2, depositing a second base electrode layer BELT2_2 on the first base electrode layer BELT2_1, and depositing a third base electrode layer BELT2_3 on the second base electrode layer BELT2_2.

The first base electrode layer BELT2_1 may be deposited to have a thickness of 30 Å to 50 Å.

The first base electrode layer BELT2_1 may include a material for forming a first electrode layer ELT2_1. For example, the first base electrode layer BELT2_1 may include titanium (Ti) and/or tantalum (Ta).

The second base electrode layer BELT2_2 may be deposited to have a thickness of 42 Å to 58 Å.

The second base electrode layer BELT2_2 may include a material for forming a second electrode layer ELT2_2. For example, the second base electrode layer BELT2_2 may include silver (Ag). According to one or more embodiments, the second base electrode layer BELT2_2 may include an alloy including silver (Ag). For example, the second base electrode layer BELT2_2 may include one or more of zinc (Zn) and/or copper (Cu) and silver (Ag). According to one or more embodiments, the second base electrode layer BELT2_2 may include a ternary silver (Ag) alloy formed of three elements.

The third base electrode layer BELT2_3 may be deposited to have a thickness of 1000 Å to 3000 Å.

The third base electrode layer BELT2_3 may include a material for forming a third electrode layer ELT2_3. For example, the third base electrode layer BELT2_3 may include a transparent conductive oxide (TCO) material. According to one or more embodiments, the third base electrode layer BELT2_3 may include one or more selected from the group consisting of indium tin oxide (ITO), indium zinc oxide (IZO), indium gallium zinc oxide (IGZO), and/or aluminum zinc oxide (AZO).

Referring to FIG. 9, in the etching the second base electrode layer and the third base electrode layer (S230), the third base electrode layer BELT2_3 and the second base electrode layer BELT2_2 may be etched to form the third electrode layer ELT2_3 and the second electrode layer ELT2_2.

Portions of the third base electrode layer BELT2_3 and the second base electrode layer BELT2_2 that do not overlap the second semiconductor layer SCL2 in a plan view may be etched. According to one or more embodiments, the third base electrode layer BELT2_3 and the second base electrode layer BELT2_2 may be etched to have ends that protrude further outward (for example, in a direction of the plane where the base layer BSL is disposed) than the light emitting element LD. According to one or more embodiments, the third base electrode layer BELT2_3 and the second base electrode layer BELT2_2 may be etched to have ends that coincide with each other. The third base electrode layer BELT2_3 and the second base electrode layer BELT2_2 may be etched to expose at least a portion of the first base electrode layer BELT2_1.

The third base electrode layer BELT2_3 and the second base electrode layer BELT2_2 may be etched through a wet etching process. According to one or more embodiments, when the third base electrode layer BELT2_3 includes indium zinc oxide (IZO), a wet etching process may be suitable. Accordingly, the third base electrode layer BELT2_3 and the second base electrode layer BELT2_2 can be wet etched together.

Referring to FIG. 10, in the etching the first base electrode layer (S250), the first base electrode layer BELT2_1 may be etched to form the first electrode layer ELT2_1.

At least a portion of the first base electrode layer BELT2_1 that does not overlap the second semiconductor layer SCL2 in a plan view may be etched. According to one or more embodiments, the first base electrode layer BELT2_1 may be etched to have ends that protrudes further outward (for example, in a direction of the plane where the base layer BSL is disposed) than the light emitting element LD. According to one or more embodiments, the first base electrode layer BELT2_1 may be etched to have ends that coincide with the third electrode layer ELT2_3 and the second electrode layer ELT2_2. The first base electrode layer ELT2_1 may be etched to expose at least a portion of the intermediate layer IL.

The first base electrode layer BELT2_1 may be etched through a wet etching process and/or a dry etching process. According to one or more embodiments, when the first base electrode layer BELT2_1 is wet etched, the first base electrode layer BELT2_1 may be wet etched by an etchant including hydrogen fluoride (HF). The first base electrode layer BELT2_1 may be deposited to have a thin thickness so that it can be easily etched.

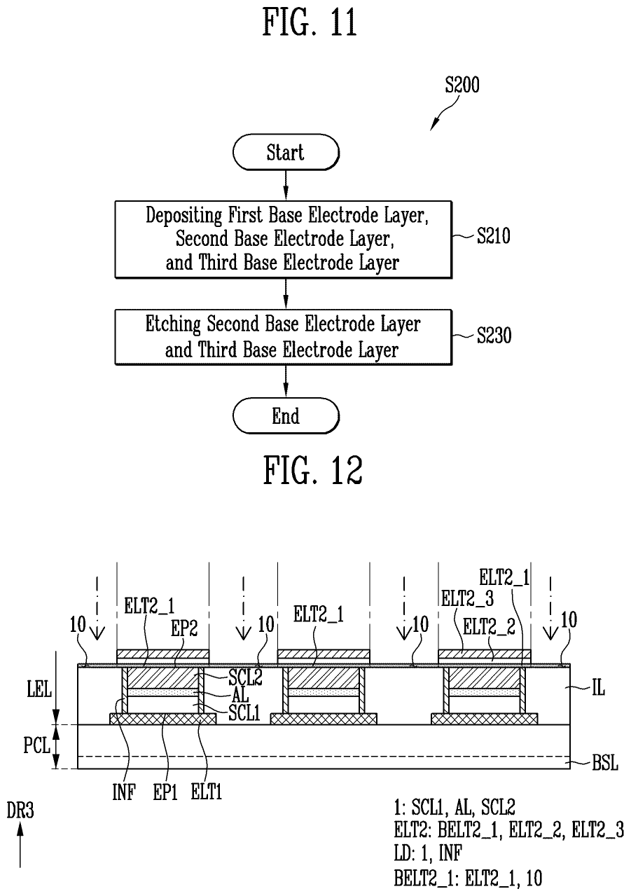

Hereinafter, a method of manufacturing a display device DD according to one or more embodiments will be described with reference to FIGS. 11 and 12.

FIG. 11 is a flowchart illustrating a step S200 of FIG. 4 in a method of manufacturing a display device according to one or more embodiments (e.g., the embodiment of FIG. 3). FIG. 12 is a cross-sectional view schematically illustrating each process in the method of manufacturing the display device according to one or more embodiments.

Compared to the embodiment of FIG. 2, the embodiment of FIG. 3 has a difference in that the etching the first base electrode layer (S250) is not included. Referring to FIG. 12, the patterning the second electrode (S200) according to one or more embodiments may include depositing the first base electrode layer, the second base electrode layer, and the third base electrode layer (S210) and etching the second base electrode layer and the third base electrode layer (S230).

Referring to FIG. 12, in the etching the second base electrode layer and the third base electrode layer (S230), the second base electrode layer BELT2_2 and the third base electrode layer BELT2_3 may be etched to expose at least a portion of the first base electrode layer BELT2_1. The first base electrode layer BELT2_1, which does not overlap the second electrode layer ELT2_2 and the third electrode layer ELT2_3 in a plan view, may be exposed to the outside (or into the air).

After the first base electrode layer BELT2_1 is deposited to have a thickness of 30 Å to 50 Å, when the first base electrode layer BELT2_1 is exposed to the outside, the first base electrode layer BELT2_1 may react with oxygen to form an insulating film. For example, when the first base electrode layer BELT2_1 is exposed to the outside (or to the air), the exposed portion may be oxidized. For example, the first base electrode layer BELT2_1, which does not overlap the second electrode layer ELT2_2 and the third electrode layer ELT2_3 in a plan view, may be oxidized to form the intermediate insulating layer 10.

According to one or more embodiments, a portion of the first base electrode layer BELT2_1 that does not overlap the second electrode layer ELT2_2 and the third electrode layer ELT2_3 in a plan view may be heat treated at a temperature of 100° C. or higher. For example, a process of applying heat of 100° C. or more to the first base electrode layer BELT2_1, which does not overlap the second electrode layer ELT2_2 and the third electrode layer ELT2_3 in a plan view, may be additionally performed. When heat is applied to the first base electrode layer BELT2_1, the first base electrode layer BELT2_1 to which heat is applied can be more easily oxidized to form the intermediate insulating layer 10.

As at least a portion of the first base electrode layer BELT2_1 forms the intermediate insulating layer 10, the intermediate insulating layer 10 may insulate the light emitting elements LD. Accordingly, the process of etching the first base electrode layer BELT2_1, which is performed to prevent current from flowing between the light emitting elements LD, may not be further performed. Accordingly, process steps for manufacturing the display device DD or the light emitting element LD can be simplified, and thus the manufacturing cost of the display device DD or the light emitting element LD can be reduced.

According to the embodiments of the present disclosure, a display device in which defects in a cathode electrode can be reduced and a method of manufacturing the same can be provided.

According to the embodiments of the present disclosure, a display device which can appropriately implement ohmic contact characteristics while ensuring appropriate light transmittance of a cathode electrode, and a method of manufacturing the same can be provided.

As described above, the optimal embodiments of the disclosure have been disclosed through the detailed description and the drawings. However, those skilled in the art or those of ordinary skill in the art will appreciate that various modifications and changes are possible without departing from the spirit and technical scope of the present disclosure as set forth in the claims below.

Therefore, the technical protection scope of the present disclosure is not limited to the detailed description described in the present disclosure, but should be determined by the appended claims.

What is claimed is:

1. A display device comprising:
a first electrode;
a semiconductor stacked member comprising a first semiconductor layer, a second semiconductor layer, and an active layer between the first semiconductor layer and the second semiconductor layer, and located on the first electrode; and
a second electrode on the semiconductor stacked member,
the second electrode comprising:
a first electrode layer on the semiconductor stacked member;
a second electrode layer on the first electrode layer, the second electrode layer having a lower sheet resistance than the first electrode layer; and
a third electrode layer on the second electrode layer, the third electrode layer comprising a transparent conductive material.

2. The display device of claim 1, wherein the first electrode layer comprises titanium (Ti) or tantalum (Ta).

3. The display device of claim 2, wherein the first electrode layer has a thickness of 30 Å to 50 Å.

4. The display device of claim 1, wherein the second electrode layer comprises silver (Ag).

5. The display device of claim 4, wherein the second electrode layer further comprises zinc (Zn) or copper (Cu).

6. The display device of claim 4, wherein the second electrode layer has a thickness of 42 Å to 58 Å.

7. The display device of claim 5, wherein the sheet resistance of the second electrode layer is 20 Ω/sq to 30 Ω/sq.

8. The display device of claim 1, wherein the second electrode layer is in contact with the first electrode layer.

9. The display device of claim 1, wherein the third electrode layer comprises indium zinc oxide (IZO).

10. The display device of claim 9, wherein the third electrode layer has a thickness of 1000 Å to 3000 Å.

11. The display device of claim 10, wherein the first electrode layer, the second electrode layer, and the third electrode layer have ends that coincide with each other.

12. The display device of claim 10, further comprising:
an intermediate insulating layer on a same layer as the first electrode layer,
wherein the intermediate insulating layer is formed integrally with the first electrode layer, and
wherein the intermediate insulating layer comprises titanium oxide (TiOx) or tantalum oxide (TaOx).

13. The display device of claim 12, wherein the second electrode layer is in contact with the first electrode layer and the third electrode layer, and
wherein an upper surface of the intermediate insulating layer is exposed by the second electrode layer and the third electrode layer.

14. A method of manufacturing a display device comprising:
patterning a first electrode on a base layer;
forming a semiconductor stacked member on the first electrode; and
patterning a second electrode on the semiconductor stacked member,
wherein the patterning the second electrode comprising:
forming a first electrode layer on the semiconductor stacked member, the first electrode layer comprising titanium (Ti) or tantalum (Ta);
forming a second electrode layer on the first electrode layer, the second electrode layer having a lower sheet resistance than the first electrode layer; and
forming a third electrode layer on the second electrode layer, the third electrode layer comprising a transparent conductive material.

15. The method of claim 14, wherein the forming the first electrode layer on the semiconductor stacked member comprises:
depositing a first base electrode layer to have a thickness of 30 Å to 50 Å on the semiconductor stacked member.

16. The method of claim 15, wherein the forming the second electrode layer on the first electrode layer comprises:
depositing a second base electrode layer on the first base electrode layer,
wherein the second base electrode layer comprises silver (Ag) and has a thickness of 42 Å to 58 Å.

17. The method of claim 16, wherein the forming the third electrode layer on the second electrode layer comprises:
depositing a third base electrode layer on the second base electrode layer,
wherein the third base electrode layer comprises indium zinc oxide (IZO) and has a thickness of 1000 Å to 3000 Å.

18. The method of claim 17, wherein the patterning the second electrode comprises:
etching the first base electrode layer, the second base electrode layer, and the third base electrode layer,
wherein the first base electrode layer, the second base electrode layer, and the third base electrode layer are etched to have ends that coincide with each other.

19. The method of claim 18, wherein the first base electrode layer is etched by an etchant comprising hydrogen fluoride (HF), and
wherein the second base electrode layer and the third base electrode layer are wet etched.

20. The method of claim 17, wherein the patterning the second electrode comprises:
etching the second base electrode layer and the third base electrode layer,
wherein the second base electrode layer and the third base electrode layer are etched to expose at least a portion of the first base electrode layer that does not overlap the semiconductor stacked member in a plan view.
